(19) United States
(12) Patent Application Publication
(10) Pub. No.: US 2017/0314161 A1
(43) Pub. Date: Nov. 2, 2017

(54) METHOD OF MANUFACTURING SILICON CARBIDE SINGLE CRYSTAL

(71) Applicant: Sumitomo Electric Industries, Ltd., Osaka-shi, Osaka (JP)

(72) Inventors: Sho SASAKI, Itami-shi, Hyogo (JP); Eiryo TAKASUKA, Itami-shi, Hyogo (JP); Shin HARADA, Itami-shi, Hyogo (JP); Tsutomu HORI, Itami-shi, Hyogo (JP)

(73) Assignee: Sumitomo Electric Industries, Ltd., Osaka-shi, Osaka (JP)

(21) Appl. No.: 15/520,488

(22) PCT Filed: Nov. 18, 2015
(86) PCT No.: PCT/JP2015/082373

§ 371 Date: Apr. 20, 2017

(30) Foreign Application Priority Data
Nov. 25, 2014 (JP) 2014-237972

(51) Int. Cl. C30B 29/36; C30B 23/06

(52) U.S. Cl. CPC C30B 29/36; C30B 23/066

(57) ABSTRACT

A crucible having a tubular inner surface is prepared. A source material is arranged so as to make contact with the inner surface, and a seed crystal is arranged in the crucible so as to face the source material. A silicon carbide single crystal grows on the seed crystal by sublimation of the source material. The inner surface is formed of a first region surrounding the source material and a second region other than the first region. In the growing a silicon carbide single crystal, an amount of heat per unit area in the first region is smaller than an amount of heat per unit area in the second region.

### TECHNICAL FIELD

The present disclosure relates to methods of manufacturing silicon carbide single crystals.

### BACKGROUND ART

In recent years, silicon carbide has been increasingly employed as a material forming a semiconductor device in order to allow for higher breakdown voltage, lower loss and the like of the semiconductor device.

Japanese National Patent Publication No. 2012-510951 (PTD 1) describes a crucible for manufacturing a silicon carbide single crystal by sublimation. A resistive heater is provided to surround an outer surface of the crucible.

### CITATION LIST

### Patent Document

PTD 1: Japanese National Patent Publication No. 2012-510951

### SUMMARY OF INVENTION

### Technical Problem

An object of one embodiment of the present disclosure is to provide a method of manufacturing a silicon carbide single crystal capable of improving the growth rate of a silicon carbide single crystal.

### Solution to Problem

A method of manufacturing a silicon carbide single crystal according to one embodiment of the present disclosure includes the following steps. A crucible having a tubular inner surface is prepared. A source material is arranged so as to make contact with the inner surface, and a seed crystal is arranged in the crucible so as to face the source material. A silicon carbide single crystal grows on the seed crystal by sublimation of the source material. The inner surface is formed of a first region surrounding the source material and a second region other than the first region. In the growing a silicon carbide single crystal, an amount of heat per unit area in the first region is smaller than an amount of heat per unit area in the second region.

### Advantageous Effects of Invention

According to the above, a method of manufacturing a silicon carbide single crystal capable of improving the growth rate of a silicon carbide single crystal can be provided.

### BRIEF DESCRIPTION OF DRAWINGS

FIG. 1 is a flowchart schematically showing a method of manufacturing a silicon carbide single crystal according to a first embodiment.

FIG. 2 is a schematic sectional view showing a step of arranging a source material and a seed crystal in the method of manufacturing a silicon carbide single crystal according to the first embodiment.

FIG. 3 is a schematic perspective view showing the configuration of a second resistive heater.

FIG. 4 is a schematic plan view showing the configuration of the second resistive heater and electrodes.

FIG. 5 is a schematic developed view showing a positional relationship between the second resistive heater and an inner surface of a crucible in a method of manufacturing a silicon carbide single crystal according to a second embodiment, where an axial direction of the inner surface represents a vertical direction and a circumferential direction of the inner surface represents a horizontal direction.

FIG. 6 is a schematic developed view showing a positional relationship between the second resistive heater and the inner surface of the crucible in a method of manufacturing a silicon carbide single crystal according to a third embodiment, where the axial direction of the inner surface represents a vertical direction and the circumferential direction of the inner surface represents a horizontal direction.

FIG. 7 is a schematic sectional view taken along line VII-VII in a direction of arrows in FIG. 6.

FIG. 8 is a schematic sectional view taken along line VIII-VIII in a direction of arrows in FIG. 6.

FIG. 9 is a schematic sectional view taken along line IX-IX in a direction of arrows in FIG. 6.

FIG. 10 is a schematic developed view showing a positional relationship between the second resistive heater and the inner surface of the crucible in a method of manufacturing a silicon carbide single crystal according to a fourth embodiment, where the axial direction of the inner surface represents a vertical direction and the circumferential direction of the inner surface represents a horizontal direction.

FIG. 11 is a schematic sectional view taken along line XI-XI in a direction of arrows in FIG. 10.

FIG. 12 is a schematic sectional view showing the step of arranging the source material and the seed crystal in a method of manufacturing a silicon carbide single crystal according to a fifth embodiment.

FIG. 13 is a schematic sectional view showing the step of arranging the source material and the seed crystal in a method of manufacturing a silicon carbide single crystal according to a sixth embodiment.

FIG. 14 is a schematic sectional view showing a step of growing a silicon carbide single crystal in the method of manufacturing a silicon carbide single crystal according to the first embodiment.

FIG. 15 is a diagram showing a relationship between temperature of the crucible and time.

FIG. 16 is a diagram showing a relationship between pressure in a chamber and time.

FIG. 17 is a functional block diagram showing a method of performing feedback control of electric power supplied to a heating unit.

### DESCRIPTION OF EMBODIMENTS

### Description of Embodiments of the Present Disclosure

According to the manufacturing device described in Japanese National Patent Publication No. 2012-510951, the resistive heater is arranged to surround the periphery of the source material arranged in the crucible. When the source material is heated using this resistive heater, the temperature of a peripheral portion of the source material become higher than the temperature of a central portion of the source material. As a result, some of a source material gas that has sublimated at the peripheral portion of the source material recrystallizes at the central portion of the source material, without reaching a seed crystal. This results in a reduced growth rate of the silicon carbide single crystal as compared to when the source material gas sublimates uniformly from the surface of the source material.

(1) A method of manufacturing a silicon carbide single crystal according to one embodiment of the present disclosure includes the following steps. A crucible having a tubular inner surface is prepared. A source material is arranged so as to make contact with the inner surface, and a seed crystal is arranged in the crucible so as to face the source material. A silicon carbide single crystal grows on the seed crystal by sublimation of the source material. The inner surface is formed of a first region surrounding the source material and a second region other than the first region. In the growing a silicon carbide single crystal, an amount of heat per unit area in the first region is smaller than an amount of heat per unit area in the second region. The in-plane uniformity of the temperature of the source material can thereby be improved, thus preventing a source material gas that has sublimated at a peripheral portion of the source material from recrystallizing at a central portion of the source material. As a result, the growth rate of the silicon carbide single crystal can be improved.

(2) In the method of manufacturing a silicon carbide single crystal according to (1) above, in the growing a silicon carbide single crystal, the source material may be heated by a resistive heater.

(3) In the method of manufacturing a silicon carbide single crystal according to (2) above, when viewed along a direction perpendicular to the inner surface, an area of overlap of the resistive heater and the first region may be smaller than an area of overlap of the resistive heater and the second region.

(4) in the method of manufacturing a silicon carbide single crystal according to (2) above, in a direction perpendicular to the inner surface, a first portion of the resistive heater facing the first region may be greater in thickness than a second portion of the resistive heater facing the second region.

(5) In the method of manufacturing a silicon carbide single crystal according to (2) above, the source material has a first surface facing the seed crystal. The seed crystal has a second surface facing the first surface. The resistive heater includes a third portion having a first thickness and a fourth portion having a second thickness greater than the first thickness, in a direction perpendicular to the inner surface. An interface between the third portion and the fourth portion may be located between the first surface and the second surface in an axial direction of the tubular inner surface.

(6) In the method of manufacturing a silicon carbide single crystal according to (1) above, in the growing a silicon carbide single crystal, the source material may be heated by an induction coil.

(7) In the method of manufacturing a silicon carbide single crystal according to (6) above, the induction coil includes a first coil provided to surround the first region, and a second coil connected to the first coil and provided to surround the second region. A number of turns of the first coil per unit length in an axial direction of the tubular inner surface may be smaller than a number of turns of the second coil per unit length in the axial direction.

(8) In the method of manufacturing a silicon carbide single crystal according to (6) above, the induction coil includes a first coil provided to surround the first region, and a second coil not connected to the first coil and provided to surround the second region. In the growing a silicon carbide single crystal, electric current supplied to the first coil may be smaller than electric current supplied to the second coil.

### Details of Embodiments of the Present Disclosure

Details of embodiments of the present disclosure will be described below based on the drawings. It is noted that the same or corresponding parts are designated by the same reference numbers in the following drawings, and description thereof will not be repeated. Regarding crystallographic indications in the present specification, an individual orientation is represented by [ ], a group orientation is represented by < >, an individual plane is represented by ( ), and a group plane is represented by { }. In addition, a negative crystallographic index is normally expressed by putting “-” (bar) above a numeral, but is expressed by putting a negative sign before the numeral in the present specification.

### First Embodiment

A method of manufacturing a silicon carbide single crystal according to a first embodiment is described.

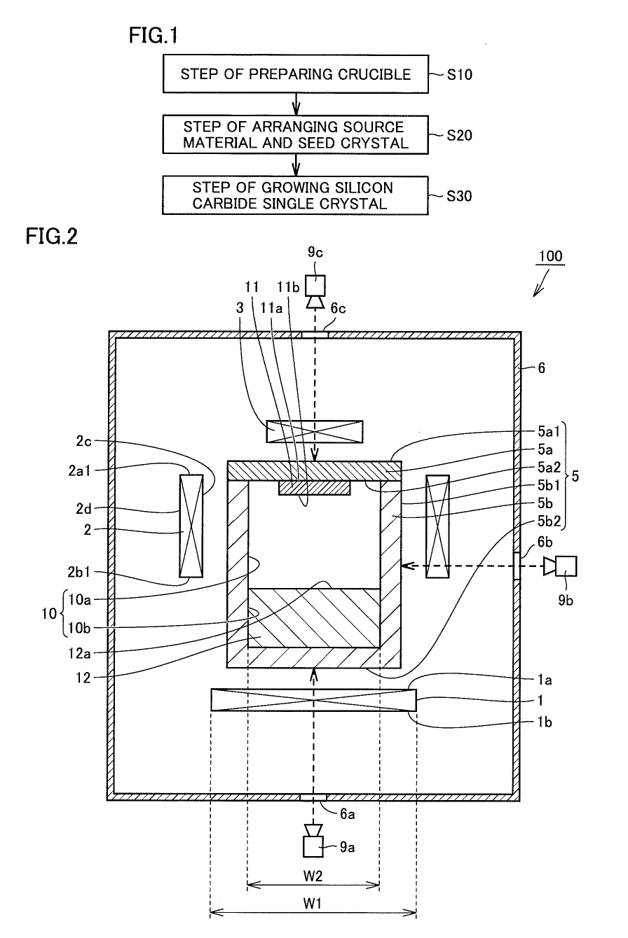

First, a step of preparing a crucible (S10: FIG. 1) is performed. Specifically, a device 100 of manufacturing a silicon carbide single crystal is prepared. As shown in FIG. 2, device 100 of manufacturing a silicon carbide single crystal according to the first embodiment mainly has a crucible 5, a first resistive heater 1, a second resistive heater 2, a third resistive heater 3, a chamber 6, a lower pyrometer 9a, a lateral pyrometer 9b, and an upper pyrometer 9c. Crucible 5 has a top surface 5a1, a bottom surface 5b2 opposite to top surface 5a1, and a tubular inner surface 10. Crucible 5 has a pedestal 5a configured to be able to hold a seed crystal 11, and an accommodation unit 5b configured to be able to accommodate a silicon carbide source material 12. Pedestal 5a has a seed crystal holding surface 5a2 in contact with a backside surface 11a of seed crystal 11, and top surface 5a1 opposite to seed crystal holding surface 5a2. Accommodation unit 5b has an outer surface 5b1, inner surface 10, and bottom surface 5b2. Each of outer surface 5b1 and inner surface 10 has a tubular shape, and preferably a cylindrical shape. Inner surface 10 is formed of a first region 10b surrounding source material 12 once source material 12 is arranged in accommodation unit 5b, and a second region 10a other than first region 10b.

Each of first resistive heater 1, second resistive heater 2 and third resistive heater 3 is provided outside crucible 5 and inside chamber 6. A heat insulator (not shown) may be provided between chamber 6 and each of first resistive heater 1, second resistive heater 2 and third resistive heater 3. First resistive heater 1 is provided to face bottom surface 5b2. First resistive heater 1 is spaced from bottom surface 5b2. First resistive heater 1 has an upper surface 1a facing bottom surface 5b2, and a lower surface 1b opposite to upper surface 1a. Second resistive heater 2 is arranged to surround outer surface 5b1. Second resistive heater 2 is spaced from outer surface 5b1. The second resistive heater includes, in a direction from bottom surface 5b2 toward top surface 5a1, a first surface 2a1 located on the side close to top surface 5a1, a second surface 2b1 located on the side close to bottom surface 5b2, a third surface 2c facing outer surface 5b1, and a fourth surface 2d opposite to third surface 2c. Third resistive heater 3 is provided to face top surface 5a1. Third resistive heater 3 is spaced from top surface 5a1. When viewed along a direction parallel to bottom surface 5b2, a width W1 of upper surface 1a of first resistive heater 1 is preferably greater than a width W2 of the interior of crucible 5 (that is, width W2 of source material 12), and more preferably greater than the width of bottom surface 5b2. The uniformity of the temperature of source material 12 in a direction parallel to a surface 12a can thereby be improved.

Lower pyrometer 9a is provided outside chamber 6 in a position facing bottom surface 5b2, and configured to be able to measure a temperature of bottom surface 5b2 through a window 6a. Lower pyrometer 9a is provided in a position facing first resistive heater 1, and may be configured to be able to measure a temperature of first resistive heater 1. Lateral pyrometer 9b is provided outside chamber 6 in a position facing outer surface 5b1, and configured to be able to measure a temperature of outer surface 5b1 through a window 6b. Lateral pyrometer 9b is provided in a position facing second resistive heater 2, and may be configured to be able to measure a temperature of second resistive heater 2. Upper pyrometer 9c is provided outside chamber 6 in a position facing top surface 5a1, and configured to be able to measure a temperature of top surface 5a1 through a window 6c. Upper pyrometer 9c is provided in a position facing third resistive heater 3, and may be configured to be able to measure a temperature of third resistive heater 3.

A pyrometer manufactured by CHINO Corporation (model number: IR-CAH8TN6) can be used, for example, as pyrometers 9a, 9b and 9c. The pyrometer has measurement wavelengths of 1.55 μm and 0.9 μm, for example. The pyrometer has a set value for emissivity of 0.9, for example. The pyrometer has a distance coefficient of 300, for example. A measurement diameter of the pyrometer is determined by dividing a measurement distance by the distance coefficient. If the measurement distance is 900 mm, for example, the measurement diameter is 3 mm.

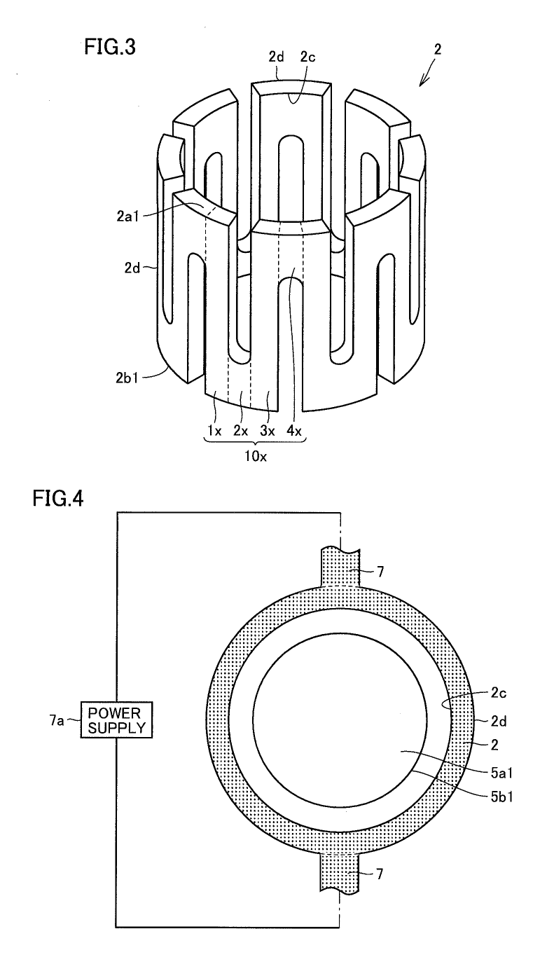

As shown in FIGS. 2 and 3, second resistive heater 2 has a fifth portion 1x extending along a direction from top surface 5a1 toward bottom surface 5b2, a sixth portion 2x provided continuously with fifth portion 1x on the side close to bottom surface 5b2 and extending along a circumferential direction of outer surface 5b1, a seventh portion 3x provided continuously with sixth portion 2x and extending along the direction from bottom surface 5b2 toward top surface 5a1, and an eighth portion 4x provided continuously with seventh portion 3x on the side close to top surface 5a1 and extending along the circumferential direction of outer surface 5b1. Fifth portion 1x, sixth portion 2x, seventh portion 3x and eighth portion 4x constitute a heater unit 10x. Second resistive heater 2 is arranged annularly by a plurality of successively provided heater units 10x.

As shown in FIG. 4, when viewed along the direction from top surface 5a1 toward bottom surface 5b2, second resistive heater 2 is provided to surround outer surface 5b1 and has a ring shape. A pair of electrodes 7 is provided in contact with fourth surface 2d of second resistive heater 2. When viewed along a direction perpendicular to top surface 5a1, the pair of electrodes 7 and top surface 5a1 may be aligned with each other. The pair of electrodes 7 is connected to a power supply 7a. Power supply 7a is configured to be able to supply electric power to second resistive heater 2. Preferably, second resistive heater 2 constitutes a parallel circuit.

It is noted that each of crucible 5, the heat insulator, first resistive heater 1, second resistive heater 2 and third resistive heater 3 is made of carbon, for example, and preferably made of graphite. The carbon (graphite) may contain impurities which are incorporated therein during manufacture. Electrodes 7 may be made of carbon (preferably graphite), for example, or may be made of metal such as copper.

Next, a step of arranging a source material and a seed crystal (S20: FIG. 1) is performed. Specifically, as shown in FIG. 2, seed crystal 11 and source material 12 are arranged in crucible 5. Source material 12 is provided in accommodation unit 5b of crucible 5. Source material 12 is a source material containing silicon carbide, for example, and preferably powders of polycrystalline silicon carbide. Seed crystal 11 is arranged in crucible 5 so as to face source material 12. Seed crystal 11 is fixed to seed crystal holding surface 5a2 with an adhesive, for example. Seed crystal 11 is a substrate of hexagonal silicon carbide having a polytype of 4H, for example. Source material 12 has a surface 12a (first surface 12a) facing seed crystal 11. Seed crystal 11 has a surface 11b (second surface 11b) facing first surface 12a, and backside surface 11a fixed to seed crystal holding surface 5a2. Surface 11b has a diameter of 100 mm or more, for example, and preferably 150 mm or more. Surface 11b may be a plane having an off angle of about 8° or less relative to a {0001} plane, for example, or may be a plane having an off angle of about 8° or less relative to a (0001) plane.

Source material 12 is arranged so as to make contact with inner surface 10. A region surrounding source material 12 is first region 10b, and a region of inner surface 10 other than first region 10b is second region 10a. That is, second region 10a does not surround source material 12, and is spaced from source material 12. First region 10b may be in contact with source material 12 or may be spaced from part of source material 12, as long as it surrounds source material 12. For example, source material 12 is arranged in accommodation unit 5b such that second surface 2b1 of second resistive heater 2 is located on the side close to top surface 5a1 with respect to surface 12a of silicon carbide source material 12 in the direction perpendicular to top surface 5a1.

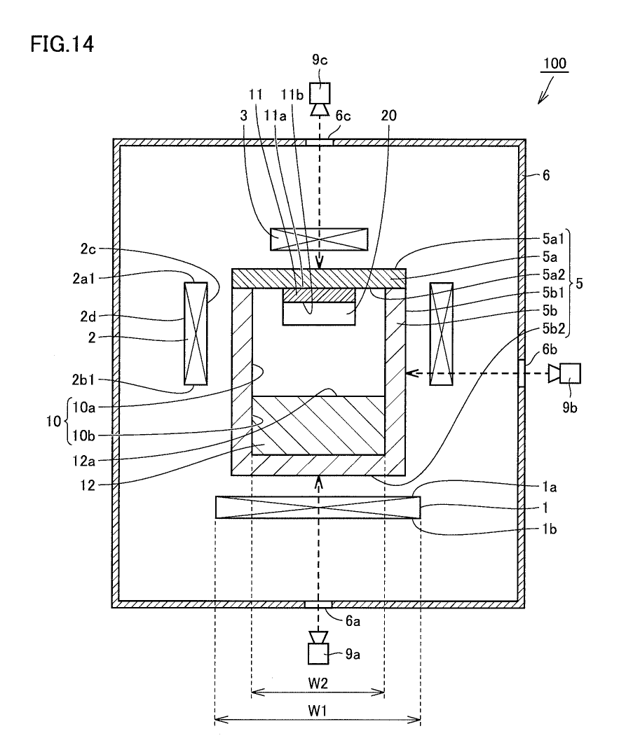

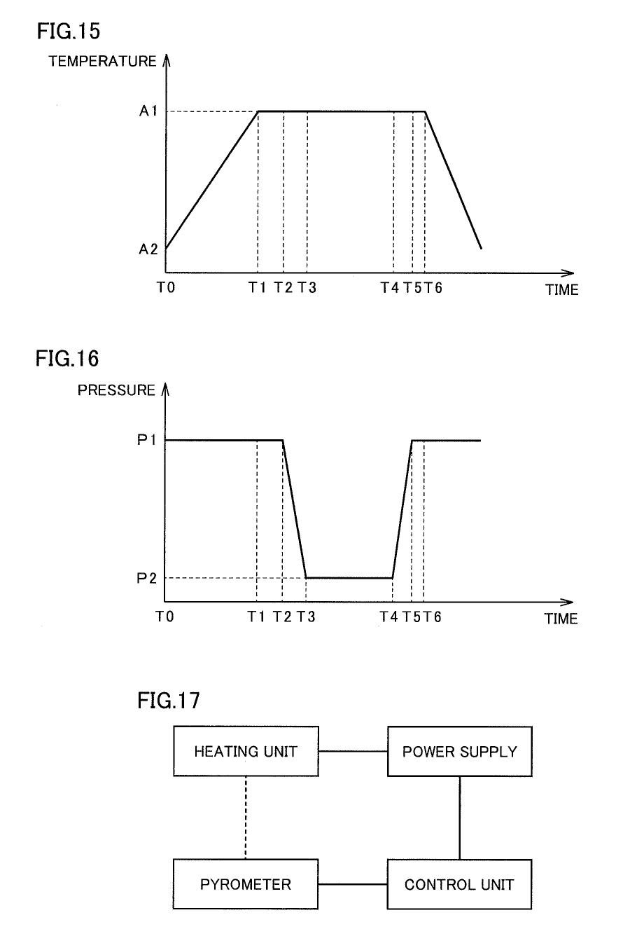

Next, a step of growing a silicon carbide single crystal (S30: FIG. 1) is performed. As shown in FIG. 14, a silicon carbide single crystal 20 is grown on surface 11b of seed crystal 11 by sublimation of source material 12. Specifically, source material 12 is heated by first resistive heater 1, second resistive heater 2 and third resistive heater 3. As shown in FIG. 15, crucible 5 having a temperature A2 at time T0 is heated to a temperature A1 at time T1. Temperature A2 is room temperature, for example. Temperature A1 is a temperature between 2000° C. or more and 2400° C. or less, for example. Both source material 12 and seed crystal 11 are heated such that the temperature decreases from bottom surface 5b2 toward top surface 5a1. Crucible 5 is maintained at temperature A1 between time T1 and time T6. As shown in FIG. 16, the pressure in chamber 6 is maintained at a pressure P1 between time T0 and time T2. Pressure P1 is atmospheric pressure, for example. An atmospheric gas in chamber 6 is inert gas such as argon gas, helium gas or nitrogen gas.

At time T2, the pressure in chamber 6 is reduced from pressure P1 to a pressure P2. Pressure P2 is 0.5 kPa or more and 2 kPa or less, for example. The pressure in chamber 6 is maintained at pressure P2 between time T3 and time T4. Silicon carbide source material 12 starts to sublimate between time T2 and time T3. The sublimated silicon carbide recrystallizes on surface 11b of seed crystal 11. The pressure in chamber 6 is maintained at pressure P2 between time T3 and time T4. Between time T3 and time T4, silicon carbide source material 12 continues to sublimate, so that silicon carbide single crystal 20 (see FIG. 14) grows on surface 11b of seed crystal 11. That is, silicon carbide single crystal 20 grows on surface 11b of seed crystal 11 by sublimation of silicon carbide source material 12 by means of first resistive heater 1, second resistive heater 2 and third resistive heater 3.

In the step of growing the silicon carbide single crystal, an amount of heat per unit area in first region 10b is smaller than an amount of heat per unit area in second region 10a. Specifically, an amount of heat per unit area which is supplied to first region 10b from a heat source external to crucible 5 is smaller than an amount of heat per unit area which is supplied to second region 10a. Preferably, an amount of heat per unit area which is supplied to first region 10b from second resistive heater 2 is smaller than an amount of heat per unit area which is supplied to second region 10a from second resistive heater 2. Preferably, between time T2 and time T5, the amount of heat per unit area in first region 10b is kept smaller than the amount of heat per unit area in second region 10a.

In the step of growing the silicon carbide single crystal, silicon carbide source material 12 is maintained at a temperature at which silicon carbide sublimates, and seed crystal 11 is maintained at a temperature at which silicon carbide recrystallizes. Specifically, the temperature of each of silicon carbide source material 12 and seed crystal 11 is controlled as follows, for example. The temperature of outer surface 5b1 is measured using lateral pyrometer 9b. As shown in FIG. 17, the temperature of outer surface 5b1 measured by lateral pyrometer 9b is transmitted to a control unit. In the control unit, the temperature of outer surface 5b1 is compared with a desired temperature. When the temperature of outer surface 5b1 is higher than the desired temperature, a command to reduce electric power supplied to second resistive heater 2 as a heating unit is issued to power supply 7a (see FIG. 4), for example. On the contrary, when the temperature of outer surface 5b1 is lower than the desired temperature, a command to increase electric power supplied to second resistive heater 2 is issued to power supply 7a, for example. That is, power supply 7a supplies electric power to second resistive heater 2 as the heating unit based on the command from the control unit. As described above, the temperature of outer surface 5b1 is controlled at the desired temperature by determination of the electric power supplied to second resistive heater 2 based on the temperature of outer surface 5b1 measured by lateral pyrometer 9b. Alternatively, the temperature of outer surface 5b1 may be controlled at the desired temperature by determination of the electric power supplied to second resistive heater 2 based on the temperature of second resistive heater 2 measured by lateral pyrometer 9b.

Similarly, the temperature of bottom surface 5b2 is controlled at a desired temperature by determination of the electric power supplied to first resistive heater 1 based on the temperature of bottom surface 5b2 measured by lower pyrometer 9a. Alternatively, the temperature of bottom surface 5b2 may be controlled at the desired temperature by determination of the electric power supplied to first resistive heater 1 based on the temperature of first resistive heater 1 measured by lower pyrometer 9a. Similarly, the temperature of top surface 5a1 is controlled at a desired temperature by determination of the electric power supplied to third resistive heater 3 based on the temperature of top surface 5a1 measured by upper pyrometer 9c. Alternatively, the temperature of top surface 5a1 may be controlled at the desired temperature by determination of the electric power supplied to third resistive heater 3 based on the temperature of third resistive heater 3 measured by upper pyrometer 9c. It is noted that when an induction coil is used instead of the resistive heaters as the heating unit, electric current supplied to the induction coil may be controlled instead of control of the electric power supplied to the resistive heaters.

Then, between time T4 and time T5, the pressure in chamber 6 increases from pressure P2 to pressure P1 (see FIG. 16). Because of the pressure increase in chamber 6, the sublimation of silicon carbide source material 12 is suppressed. The step of growing the silicon carbide single crystal is thereby substantially completed. At time T6, the heating of crucible 5 is stopped to cool crucible 5. After the temperature of crucible 5 approaches the room temperature, silicon carbide single crystal 20 is removed from crucible 5.

Next, a function and effect of the method of manufacturing a silicon carbide single crystal according to the first embodiment will be described.

In accordance with the method of manufacturing a silicon carbide single crystal according to the first embodiment, crucible 5 having tubular inner surface 10 is prepared. Source material 12 is arranged so as to make contact with inner surface 10, and seed crystal 11 is arranged in crucible 5 so as to face source material 12. Silicon carbide single crystal 20 grows on seed crystal 11 by sublimation of source material 12. Inner surface 10 is formed of first region 10b surrounding source material 12 and second region 10a other than first region 10b. In the step of growing silicon carbide single crystal 20, the amount of heat per unit area in first region 10b is smaller than the amount of heat per unit area in second region 10a. The in-plane uniformity of the temperature of source material 12 can thereby be improved, thus preventing the source material gas that has sublimated at a peripheral portion of source material 12 from recrystallizing at a central portion of source material 12. As a result, the growth rate of silicon carbide single crystal 20 can be improved.

### Second Embodiment

Next, a method of manufacturing a silicon carbide single crystal according to a second embodiment is described. The method of manufacturing a silicon carbide single crystal according to the second embodiment is mainly different from the method of manufacturing a silicon carbide single crystal according to the first embodiment in that second surface 2b1 of second resistive heater 2 is located on the side close to bottom surface 5b2 with respect to surface 12a of source material 12, and that it has a step of arranging source material 12 in crucible 5 such that the area of overlap of second resistive heater 2 and first region 10b is smaller than the area of overlap of second resistive heater 2 and second region 10a when viewed along a direction perpendicular to inner surface 10. The other steps are approximately the same as those of the method of manufacturing a silicon carbide single crystal according to the first embodiment. The step different from the first embodiment will be mainly described below, and description of the similar steps is omitted.

The step of preparing the crucible (S10: FIG. 1) and the step of arranging the source material and the seed crystal (S20: FIG. 1) are performed. As shown in FIG. 5, second resistive heater 2 has a first portion 2b facing first region 10b and a second portion 2a facing second region 10a, when viewed along the direction perpendicular to inner surface 10. When viewed along the direction perpendicular to inner surface 10, the area of first portion 2b is smaller than the area of second portion 2a. In other words, when viewed along the direction perpendicular to inner surface 10, the area of overlap of second resistive heater 2 and first region 10b is smaller than the area of overlap of second resistive heater 2 and second region 10a.

Second portion 2a has a fifth surface 2a2 opposite to first surface 2a1. In an axial direction, fifth surface 2a2 may be located at the same level as surface 12a of source material 12, or may be located on the side close to top surface 5a1 with respect to the level of surface 12a. In the axial direction, second surface 2b1 of first portion 2b is located on the side close to bottom surface 5b2 with respect to first surface 12a. Preferably, second resistive heater 2 has fifth surface 2a2 and second surface 2b1 alternately arranged in a circumferential direction.

That is, in the step of arranging the source material and the seed crystal (S20: FIG. 1), second surface 2b1 of second resistive heater 2 is located on the side close to bottom surface 5b2 with respect to surface 12a of source material 12, and source material 12 is arranged in accommodation unit 5b such that the area of overlap of second resistive heater 2 and first region 10b is smaller than the area of overlap of second resistive heater 2 and second region 10a when viewed along the direction perpendicular to inner surface 10. After source material 12 is arranged in accommodation unit 5b, the step of growing the silicon carbide single crystal (S30: FIG. 1) is performed.

### Third Embodiment

Next, a method of manufacturing a silicon carbide single crystal according to a third embodiment is described. The method of manufacturing a silicon carbide single crystal according to the third embodiment is mainly different from the method of manufacturing a silicon carbide single crystal according to the first embodiment in that it has a step of arranging source material 12 in crucible 5 such that the thickness of first portion 2b of second resistive heater 2 facing first region 10b is greater than the thickness of second portion 2a of second resistive heater 2 facing second region 10a. The other steps are approximately the same as those of the method of manufacturing a silicon carbide single crystal according to the first embodiment. The step different from the first embodiment will be mainly described below, and description of the similar steps is omitted.

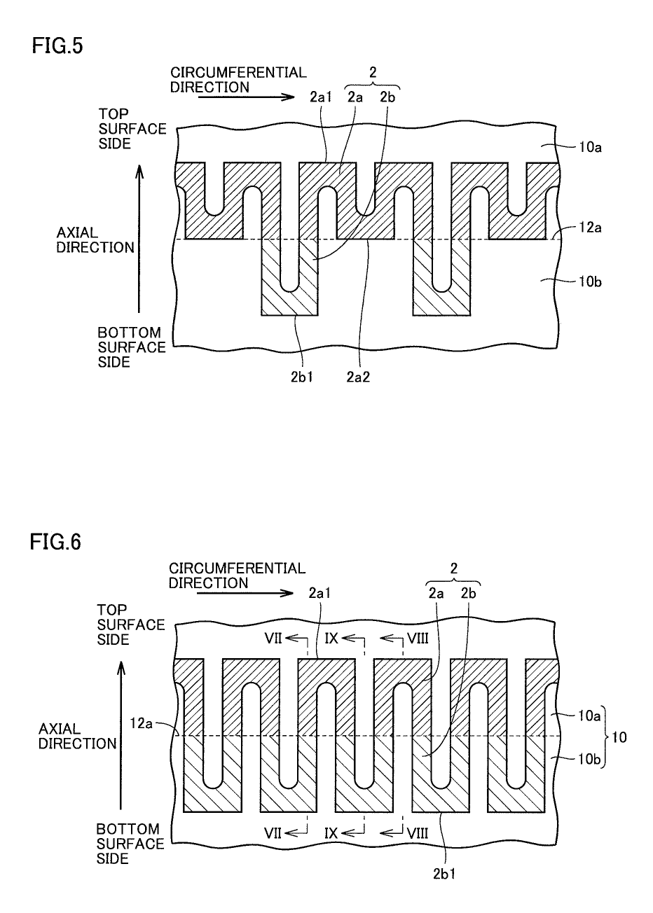

The step of preparing the crucible (S10: FIG. 1) and the step of arranging the source material and the seed crystal (S20: FIG. 1) are performed. As shown in FIG. 6, second resistive heater 2 has first portion 2b facing first region 10b and second portion 2a facing second region 10a, when viewed along the direction perpendicular to inner surface 10. When viewed along the direction perpendicular to inner surface 10, the area of first portion 2b is approximately the same as the area of second portion 2a.

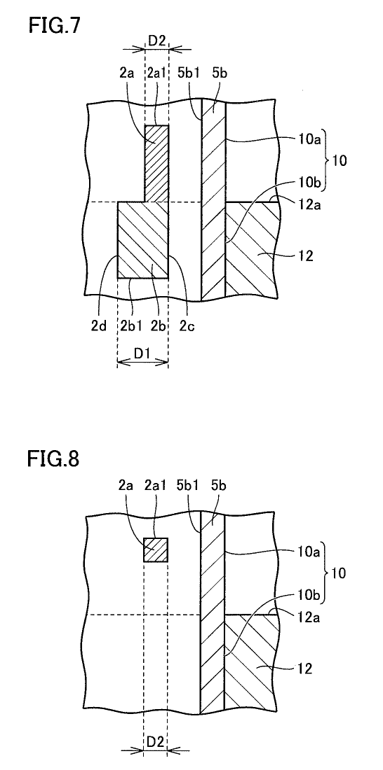

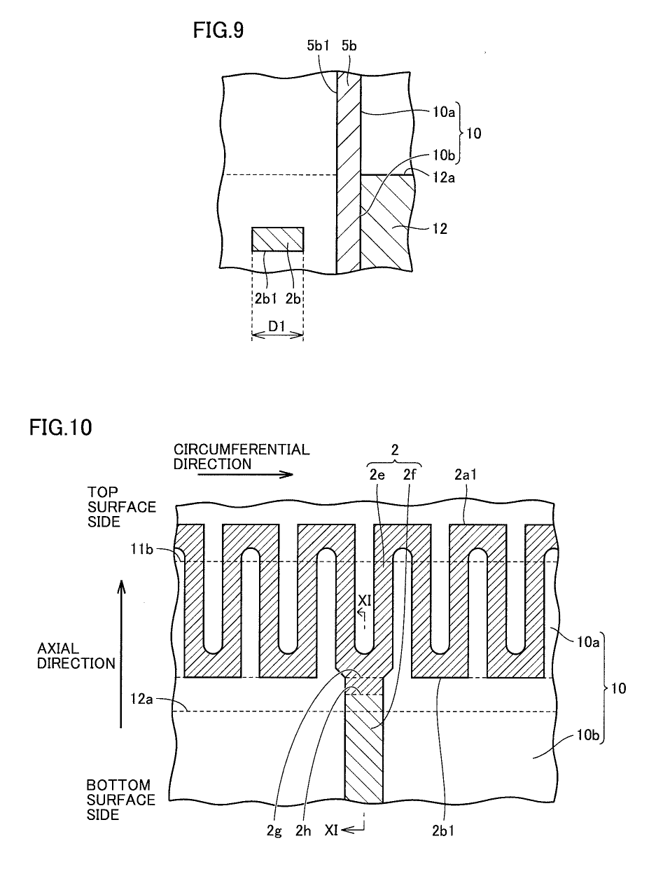

As shown in FIGS. 7, 8 and 9, in the direction perpendicular to inner surface 10, a thickness D1 of first portion 2b is greater than a thickness D2 of second portion 2a. Thickness D1 of first portion 2b may be two or more times thickness D2 of the second portion. In the direction from top surface 5a1 toward bottom surface 5b2, the thickness of each of first portion 2b and second portion 2a may be gradually increased. As shown in FIGS. 7 and 8, thickness D2 of second portion 2a may be constant along the circumferential direction. As shown in FIGS. 7 and 9, thickness D1 of first portion 2b may be constant along the circumferential direction.

That is, in the step of arranging the source material and the seed crystal (S20: FIG. 1), source material 12 is arranged in accommodation unit 5b such that the thickness of first portion 2b of second resistive heater 2 facing first region 10b is greater than the thickness of second portion 2a of second resistive heater 2 facing second region 10a in the direction perpendicular to inner surface 10. After source material 12 is arranged in accommodation unit 5b, the step of growing the silicon carbide single crystal (S30: FIG. 1) is performed.

### Fourth Embodiment

Next, a method of manufacturing a silicon carbide single crystal according to a fourth embodiment is described. The method of manufacturing a silicon carbide single crystal according to the fourth embodiment is mainly different from the method of manufacturing a silicon carbide single crystal according to the first embodiment in that second resistive heater 2 includes a third portion 2e having a first thickness and a fourth portion 2f having a second thickness greater than the first thickness in the direction perpendicular to inner surface 10, and that it has a step of arranging seed crystal 11 and source material 12 in crucible 5 such that an interface 2h between third portion 2e and fourth portion 2f is located between first surface 12a and second surface 11b in the axial direction of tubular inner surface 10. The other steps are approximately the same as those of the method of manufacturing a silicon carbide single crystal according to the first embodiment. The step different from the first embodiment will be mainly described below, and description of the similar steps is omitted.

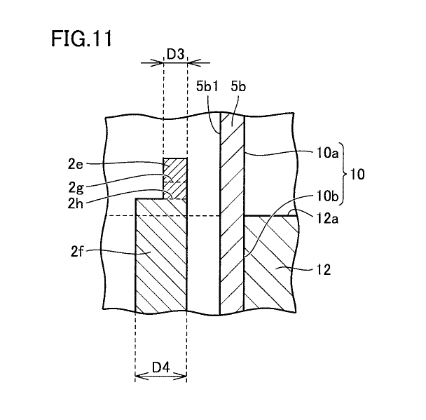

The step of preparing the crucible (S10: FIG. 1) and the step of arranging the source material and the seed crystal (S20: FIG. 1) are performed. As shown in FIGS. 10 and 11, second resistive heater 2 includes third portion 2e having a first thickness D3 and fourth portion 2f having a second thickness D4 greater than first thickness D3 in the direction perpendicular to the inner surface. Interface 2h between third portion 2e and fourth portion 2f is located between first surface 12a and second surface 11b in the axial direction parallel to tubular inner surface 10. Second thickness D4 may be two or more times first thickness D3.

As shown in FIG. 3, third portion 2e has fifth portion 1x extending along the direction from top surface 5a1 toward bottom surface 5b2, sixth portion 2x provided continuously with fifth portion 1x on the side close to bottom surface 5b2 and extending along the circumferential direction of outer surface 5b1, seventh portion 3x provided continuously with sixth portion 2x and extending along the direction from bottom surface 5b2 toward top surface 5a1, and eighth portion 4x provided continuously with seventh portion 3x on the side close to top surface 5a1 and extending along the circumferential direction of outer surface 5b1. Fifth portion 1x, sixth portion 2x, seventh portion 3x and eighth portion 4x constitute heater unit 10x. Second resistive heater 2 is arranged annularly by the plurality of successively provided heater units 10x. Fourth portion 2f is in contact with second surface 2b1 on the side close to the bottom surface of third portion 2e, and is provided to extend in a direction parallel to the axial direction. As shown in FIG. 10, third portion 2e has a ninth portion having a width that decreases in the circumferential direction from the top surface 5a1 side to the bottom surface 5b2 side, and a tenth portion having a constant width in the circumferential direction. In the axial direction, a boundary 2g between the ninth portion and the tenth portion is located at approximately the same level as second surface 2b1 of third portion 2e which is not in contact with fourth portion 2f.

That is, in the step of arranging the source material and the seed crystal (S20: FIG. 1), source material 12 is arranged in accommodation unit 5b and seed crystal 11 is fixed to pedestal 5a, such that interface 2h between third portion 2e and fourth portion 2f is located between first surface 12a and second surface 11b in the axial direction of tubular inner surface 10. After source material 12 is arranged in accommodation unit 5b, the step of growing the silicon carbide single crystal (S30: FIG. 1) is performed.

### Fifth Embodiment

Next, a method of manufacturing a silicon carbide single crystal according to a fifth embodiment is described. The method of manufacturing a silicon carbide single crystal according to the fifth embodiment is different from the method of manufacturing a silicon carbide single crystal according to the first embodiment in that it has a step of heating source material 12 using an induction coil instead of the resistive heaters. The other steps are approximately the same as those of the method of manufacturing a silicon carbide single crystal according to the first embodiment. The step different from the first embodiment will be mainly described below, and description of the similar steps is omitted.

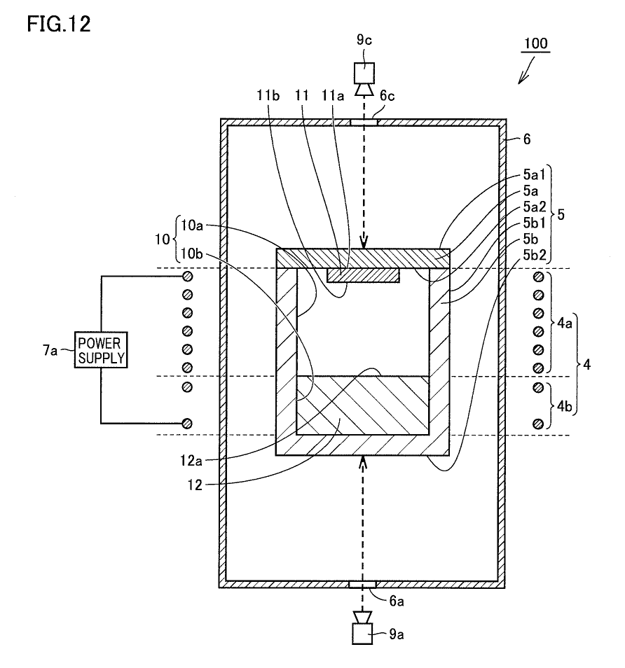

The step of preparing the crucible (S10: FIG. 1) and the step of arranging the source material and the seed crystal (S20: FIG. 1) are performed. As shown in FIG. 12, an induction coil 4 may be used instead of the resistive heaters in order to heat crucible 5. Induction coil 4 is arranged outside chamber 6, for example, and is wound to surround chamber 6. Induction coil 4 includes a first coil 4b provided to surround first region 10b, and a second coil 4a connected to first coil 4b and provided to surround second region 10a. Power supply 7a has one pole connected to first coil 4b, and the other pole connected to second coil 4a. Power supply 7a is provided to be able to supply electric current to induction coil 4. The number of turns of first coil 4b per unit length in the axial direction of tubular inner surface 10 is smaller than the number of turns of second coil 4a per unit length in the axial direction. For example, the number of turns of second coil 4a per unit length in the axial direction is two or more times the number of turns of first coil 4b per unit length in the axial direction.

That is, in the step of arranging the source material and the seed crystal (S20: FIG. 1), source material 12 is arranged in accommodation unit 5b such that the number of turns of first coil 4b per unit length in the axial direction of tubular inner surface 10 is smaller than the number of turns of second coil 4a per unit length in the axial direction.

Next, the step of growing the silicon carbide single crystal (S30: FIG. 1) is performed. Specifically, crucible 5 is heated by induction coil 4, whereby source material 12 is heated. More specifically, AC current is supplied by power supply 7a to induction coil 4, causing eddy current to be generated in crucible 5. Crucible 5 is self-heated when eddy current is generated therein. As a result, heat is transferred from self-heated crucible 5 to source material 12, to heat source material 12. In the step of growing the silicon carbide single crystal, the amount of heat per unit area in first region 10b is smaller than the amount of heat per unit area in second region 10a. Specifically, the amount of heat per unit area generated by first region 10b is smaller than the amount of heat per unit area generated by second region 10a.

### Sixth Embodiment

Next, a method of manufacturing a silicon carbide single crystal according to a sixth embodiment is described. The method of manufacturing a silicon carbide single crystal according to the sixth embodiment is different from the method of manufacturing a silicon carbide single crystal according to the fifth embodiment in that the induction coil has a first coil and a second coil, and that it has a step in which electric current supplied to the first coil is smaller than electric current supplied to the second coil. The other steps are approximately the same as those of the method of manufacturing a silicon carbide single crystal according to the fifth embodiment. The step different from the fifth embodiment will be mainly described below, and description of the similar steps is omitted.

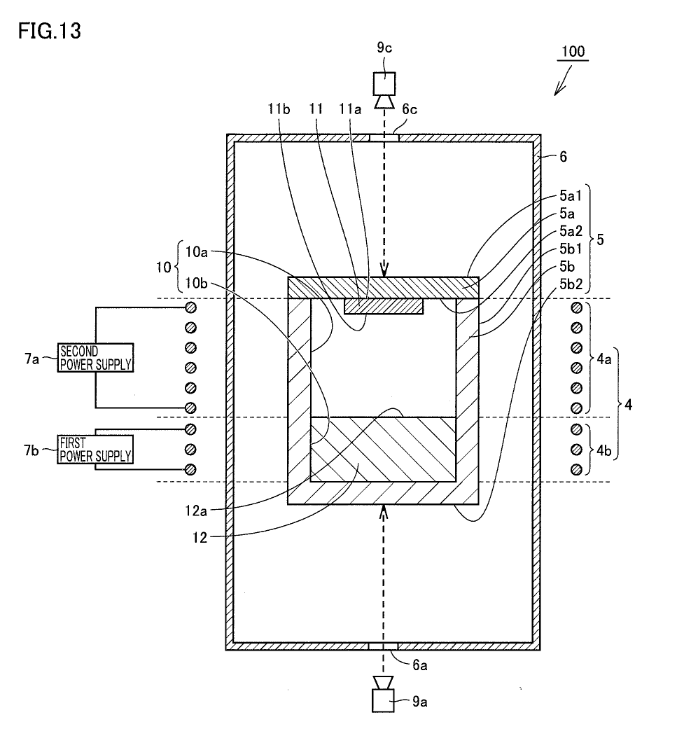

The step of preparing the crucible (S10: FIG. 1) and the step of arranging the source material and the seed crystal (S20: FIG. 1) are performed. As shown in FIG. 13, induction coil 4 is arranged outside chamber 6, for example, and is provided to surround chamber 6. Induction coil 4 includes first coil 4b provided to surround first region 10b, and second coil 4a not connected to first coil 4b and provided to surround second region 10a. That is, first coil 4b is spaced from second coil 4a. First coil 4b has one end and the other end connected to a first power supply 7b. First power supply 7b is configured to be able to supply electric current to first coil 4b. Similarly, second coil 4a has one end and the other end connected to a second power supply 7a. Second power supply 7a is configured to be able to supply electric current to second coil 4a. The number of turns of first coil 4b per unit length in the axial direction of tubular inner surface 10 is approximately the same as the number of turns of second coil 4a per unit length in the axial direction.

In the step of growing the silicon carbide single crystal, electric currents are supplied separately to first coil 4b and second coil 4a. Specifically, electric current is supplied to each of first coil 4b and second coil 4a such that the electric current supplied to first coil 4b is smaller than the electric current supplied to second coil 4a. The amount of heat per unit area generated by first region 10b is thereby smaller than the amount of heat per unit area generated by second region 10a.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

### REFERENCE SIGNS LIST

1 first resistive heater; 1a upper surface; 1b lower surface; 1x fifth portion; 2 second resistive heater; 2a second portion; 2a2 fifth surface; 2a1 first surface; 2b first portion; 2b1 second surface; 2c third surface; 2d fourth surface; 2e third portion; 2f fourth portion; 2g boundary; 2h interface; 2x sixth portion; 3 third resistive heater; 3x seventh portion; 4 induction coil; 4a second coil; 4b first coil; 4x eighth portion; 5 crucible; 5a2 seed crystal holding surface; 5a1 top surface; 5a pedestal; 5b2 bottom surface; 5b1 outer surface; 5b accommodation unit; 6 chamber; 6a, 6b, 6c window; 7 electrode; 7a power supply (second power supply); 7b first power supply; 9a lower pyrometer; 9b lateral pyrometer; 9c upper pyrometer; 10 inner surface; 10a second region; 10b first region; 10x heater unit; 11 seed crystal; 11a backside surface; 11b surface (second surface); 12 source material (silicon carbide source material); 12a surface (first surface); 20 silicon carbide single crystal; 100 manufacturing device; A1, A2 temperature; D1, D2 thickness; D3 first thickness; D4 second thickness; P1, P2 pressure; T0, T1, T2, T3, T4, T5, T6 time; W1, W2 width.

1. A method of manufacturing a silicon carbide single crystal, comprising:
preparing a crucible having a tubular inner surface;
arranging a source material so as to make contact with the inner surface, and arranging a seed crystal in the crucible so as to face the source material; and
growing a silicon carbide single crystal on the seed crystal by sublimating the source material,
the inner surface being formed of a first region surrounding the source material and a second region other than the first region,
in the growing a silicon carbide single crystal, an amount of heat per unit area in the first region being smaller than an amount of heat per unit area in the second region.

2. The method of manufacturing a silicon carbide single crystal according to claim 1, wherein
in the growing a silicon carbide single crystal, the source material is heated by a resistive heater.

3. The method of manufacturing a silicon carbide single crystal according to claim 2, wherein
when viewed along a direction perpendicular to the inner surface, an area of overlap of the resistive heater and the first region is smaller than an area of overlap of the resistive heater and the second region.

4. The method of manufacturing a silicon carbide single crystal according to claim 2, wherein
in a direction perpendicular to the inner surface, a first portion of the resistive heater facing the first region is greater in thickness than a second portion of the resistive heater facing the second region.

5. The method of manufacturing a silicon carbide single crystal according to claim 2, wherein
the source material has a first surface facing the seed crystal,
the seed crystal has a second surface facing the first surface,
the resistive heater includes a third portion having a first thickness and a fourth portion having a second thickness greater than the first thickness, in a direction perpendicular to the inner surface, and
an interface between the third portion and the fourth portion is located between the first surface and the second surface in an axial direction of the tubular inner surface.

6. The method of manufacturing a silicon carbide single crystal according to claim 1, wherein
in the growing a silicon carbide single crystal, the source material is heated by an induction coil.

7. The method of manufacturing a silicon carbide single crystal according to claim 6, wherein
the induction coil includes a first coil provided to surround the first region, and a second coil connected to the first coil and provided to surround the second region, and
a number of turns of the first coil per unit length in an axial direction of the tubular inner surface is smaller than a number of turns of the second coil per unit length in the axial direction.

8. The method of manufacturing a silicon carbide single crystal according to claim 6, wherein
the induction coil includes a first coil provided to surround the first region, and a second coil not connected to the first coil and provided to surround the second region, and
in the growing a silicon carbide single crystal, electric current supplied to the first coil is smaller than electric current supplied to the second coil.
